(19) United States
(12) Patent Application Publication
(10) Pub. No.: US 2013/0293482 A1
(43) Pub. Date: Nov. 7, 2013

(54) TRANSPARENT THROUGH-GLASS VIA

(71) Applicants: David William Burns, San Jose, CA (US); Kristopher Andrew Lavery, San Jose, CA (US)

(72) Inventors: David William Burns, San Jose, CA (US); Kristopher Andrew Lavery, San Jose, CA (US)

(73) Assignee: QUALCOMM MEMS TECHNOLOGIES, INC., San Diego, CA (US)

(21) Appl. No.: 13/464,135

(22) Filed: May 4, 2012

(51) Int. Cl. G06T 1/00; H05K 1/09; B05D 5/00; H05K 3/40; H05K 3/46; B32B 37/14; H05K 1/11; G06F 3/041

(52) U.S. Cl. 345/173; 174/266; 174/257; 345/501; 29/846; 29/852; 29/830; 156/60; 427/108

(57) ABSTRACT

This disclosure provides systems, methods and apparatus for transparent conductive vias in a transparent substrate. In one aspect, a transparent conductive via extends through a transparent substrate and electrically connects a topside conductor on a top surface of the transparent substrate and a bottom side conductor on a bottom surface of the transparent substrate. In another aspect, a transparent conductive via extends at least partially through a transparent substrate and is in electrical communication with a topside conductor on a top surface of the transparent substrate. In another aspect, a method of forming a transparent through-substrate via is provided.

### TECHNICAL FIELD

This disclosure relates generally to conductive vias and more particularly to conductive vias for electrical connection through or partially through a transparent substrate.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities. IMODs can be formed on a variety of substrates, including transparent substrates, and therefore vias can help route signals to an array of IMODs such as, for example, a display device.

Partially through electrically conductive vias in a substrate can provide electrical connection between traces, pads, devices and other electrical components on one or more layers on either side of the substrate. Through vias such as through-glass vias can provide electrical connection between one side of the substrate and the other.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus including a transparent substrate having top and bottom surfaces, a topside conductor on the top surface of transparent substrate, a bottom side conductor on the bottom surface of the transparent substrate, and a transparent conductive via extending through the transparent substrate. The transparent conductive via may electrically connect the topside conductor to the bottom side conductor. The transparent conductive via can include a via hole that extends through the transparent substrate.

In some implementations, an interior surface of the via hole can be coated with one or more transparent conductive materials. In some implementations, the thickness of the one or more transparent conductive materials can be between about 100 Å and 2 microns. Examples of transparent conductive materials include transparent conductive oxides. In some implementations, a transparent conductive via that includes a transparent conductive coating can further include a transparent conductive or non-conductive material that at least partially fills the via hole.

In some implementations, one or more transparent conductive materials fill the via hole. Examples of transparent conductive materials that can fill the via hole include a transparent conductive polymer, a nanotube-filled resin, a metal nanowire-filled resin, a particle-filled resin, a metal particle-filled resin, a polyelectrolyte, a polymer gel electrolyte, a bicontinuous phase-separated blend of a conductive polymer and a non-conductive polymer, and a microphase-separated block copolymer including conductive and non-conductive blocks.

In some implementations, one or both of the topside and bottom side conductors can be transparent. The apparatus can further include transparent conductive routing on a surface of the transparent substrate in electrical communication with the transparent conductive via.

In some implementations, the thickness of the transparent substrate can be between about 10 microns and 50 microns. In some other implementations, the thickness of the transparent substrate can be between about 50 microns and 700 microns. In some implementations, a diameter of the transparent conductive via can be between about 3 microns and 10 microns. In some other implementations, a diameter of the transparent conductive via can be between about 10 microns and 700 microns. In some implementations, the transparent conductive via can have an electrical resistance between about 10 ohms and 10,000 ohms.

In some implementations, the apparatus can include an array of transparent conductive vias that extend through the transparent substrate. The transparent conductive vias can provide an electrical connection to one or more devices, such as one or more integrated circuit, optoelectronic, or MEMS devices. In some implementations, the apparatus can be a display or touch sensor.

Another innovative aspect of the subject matter described in this disclosure can be implemented in an apparatus including a transparent substrate having top and bottom surfaces, a topside conductor on the top surface of transparent substrate, and a transparent conductive via extending at least partially through the transparent substrate. The transparent conductive via can be in electrical communication with the topside conductor.

In some implementations, the apparatus can further include a transparent ground plane disposed within the transparent substrate or on the bottom surface of the transparent substrate. The transparent conductive via can provides a conductive pathway from the topside conductor to the transparent ground plane. In some implementations, the transparent conductive via can electrically connect the topside conductor to an electrical trace or device that is positioned between the top surface and the bottom surface of the transparent substrate.

Another innovative aspect of the subject matter described in this disclosure can be implemented in an apparatus including a transparent substrate including a top surface and a bottom surface; a topside means for conducting electricity on the top surface and a bottom side means for conducting electricity on the bottom surface; and a transparent means for conducting electricity through the transparent substrate. The transparent means can electrically connect the topside means to the bottom side means. Examples of topside and bottom side means for conducting electricity include conductors such as patterned conductive lines or traces and similar structures. Examples of transparent means for conductive electricity through the transparent substrate include transparent conductive vias and similar structures.

Another innovative aspect of the subject matter described in this disclosure can be implemented in a method of forming a transparent conductive via. The method can include providing a transparent substrate having a top surface and a bottom surface, forming at least one of a topside conductor on the top surface and a bottom side conductor on the bottom surface, forming a via hole in the transparent substrate, and forming a transparent conductive via extending at least partially through the transparent substrate. The transparent conductive via can be in electrical communication with at least one of the topside conductor and the bottom side conductor.

In some implementations, forming the transparent conductive via can include filling the via hole with transparent conductive material. In some implementations, forming the transparent conductive via can include coating the via hole with a transparent conductive material. In some implementations, forming the transparent conductive via can include filling the via hole with a non-conductive transparent material. In some implementations, forming the transparent conductive via can include depositing a transparent conductive oxide on an interior surface of the via hole. In some implementations, forming the transparent conductive via can include coating the via hole with a transparent conductive polymer.

Another innovative aspect of the subject matter described in this disclosure can be implemented in a method including providing a first transparent substrate and forming a second transparent substrate on the first transparent substrate. In some implementations, the first and second transparent substrates can be laminated together. In some implementations, forming the second transparent substrate on the first transparent can include applying a spin-on dielectric or epoxy to the first transparent substrate. The first transparent substrate can include a top surface and a bottom surface, a topside conductor on the top surface of the first transparent substrate and a bottom side conductor on the bottom surface of the first transparent substrate, and a first transparent conductive via extending through the first transparent substrate. The first transparent conductive via can electrically connect the topside conductor to the bottom side conductor of the first transparent substrate. The second transparent substrate can include a top surface and a bottom surface, a topside conductor on the top surface of the second transparent substrate and a bottom side conductor on the bottom surface of the second transparent substrate, and a transparent conductive via extending through the second transparent substrate. The second transparent conductive via can electrically connect the topside conductor to the bottom side conductor of the second transparent substrate.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a perspective view of a transparent conductive via in a transparent substrate.

FIGS. 10A-10E show examples of schematic illustrations of transparent conductive vias having various shapes.

FIG. 11A shows an example of a schematic illustration of a through-substrate via hole.

FIG. 11B shows an example of a cross-sectional schematic illustration of the through-substrate via hole of FIG. 11A.

FIG. 12A shows an example of a schematic illustration of a through-substrate transparent conductive via with a coating material.

FIG. 12B shows an example of a cross-sectional schematic illustration of the through-substrate transparent conductive via with a coating material of FIG. 12A.

FIG. 13A shows an example of a through-substrate transparent conductive via with a coating material and a filler material.

FIG. 13B shows an example of a cross-sectional schematic illustration of the through-substrate transparent conductive via with a coating material and a filler material of FIG. 13A.

FIG. 14A shows an example of a schematic illustration of a through-substrate transparent conductive via with a conductive filler material.

FIG. 14B shows an example of a cross-sectional schematic illustration of the transparent through-substrate via with a filler material of FIG. 14A.

FIG. 15 shows an example of a flow diagram illustrating a method of manufacturing a transparent conductive via.

FIG. 16 shows an example of a perspective view of a transparent conductive via in electrical connection with a ground plane.

FIG. 17 shows an example of a perspective view of an array of transparent conductive vias in electrical connection with touch sensor devices.

FIG. 18 shows an example of a perspective view of an array of transparent conductive vias in electrical connection with reflective display devices.

FIG. 19 shows an example of a cross-sectional schematic illustration of a multilayer transparent substrate including a plurality of transparent conductive vias.

FIGS. 20A and 20B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Any application in which it is desirable to provide a conductive path through or partially through a transparent substrate may utilize the transparent via structures disclosed herein. Thus, the teachings are not intended to be limited to the implementations depicted solely in the Figures, but instead have wide applicability as will be readily apparent to one having ordinary skill in the art.

Some implementations described herein relate to transparent conductive vias, including transparent conductive through-substrate vias or partially through vias in a transparent substrate. Transparent conductive vias can include electrical connections extending through a substrate such as a glass panel or glass substrate to connect a topside conductor and a bottom side conductor. Such vias can be referred to as through-glass vias (TGVs). In some implementations, the electrical connections can be made to integrated circuits, optoelectronic devices, or MEMS devices formed on or attached to the transparent substrate. While some implementations described herein relate to through-substrate vias, other implementations described herein relate to vias that extend partially through a substrate.

Some implementations described herein relate to forming a transparent through-substrate via. Forming the transparent through-substrate via can include forming one or more via holes in a transparent substrate and forming a transparent conductive via extending through the transparent substrate. In some implementations, forming the transparent conductive via can include filling the via hole with electrically conductive material. In some implementations, forming the transparent conductive via can include coating the via hole with electrically conductive material.

Particular implementations of the subject matter described in this disclosure can be implemented to realize one or more of the following potential advantages. Transparent conductive vias can eliminate the use of electrical connections that are opaque to visible light and improve the overall transparency in devices that include transparent substrates, such as display devices. Transparent conductive vias can be used in active areas of a transparent device without presenting viewing obstacles and minimize or eliminate optical artifacts that generally can occur with opaque and/or specular, metal-filled vias. The use of transparent conductive vias can eliminate or reduce the need for fine-pitch flex tape that is often attached near an edge of the substrate surface. Hence, the use of transparent conductive vias can reduce the size of border regions. Transparent conductive vias can be used to make electrical connections to devices or layers formed within or on the opposite side of the transparent substrate, such as a transparent ground plane, an electrostatic shield, or a touch sensor. While many transparent conductive materials have relatively higher bulk resistance compared to metals, for relatively small vias, in some applications, the resistance of a transparent conductive material may be small compared to the overall resistance of a trace conducting electric signals from one device to another.

An example of a suitable EMS or MEMS device, to which the described implementations of a transparent conductive via may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

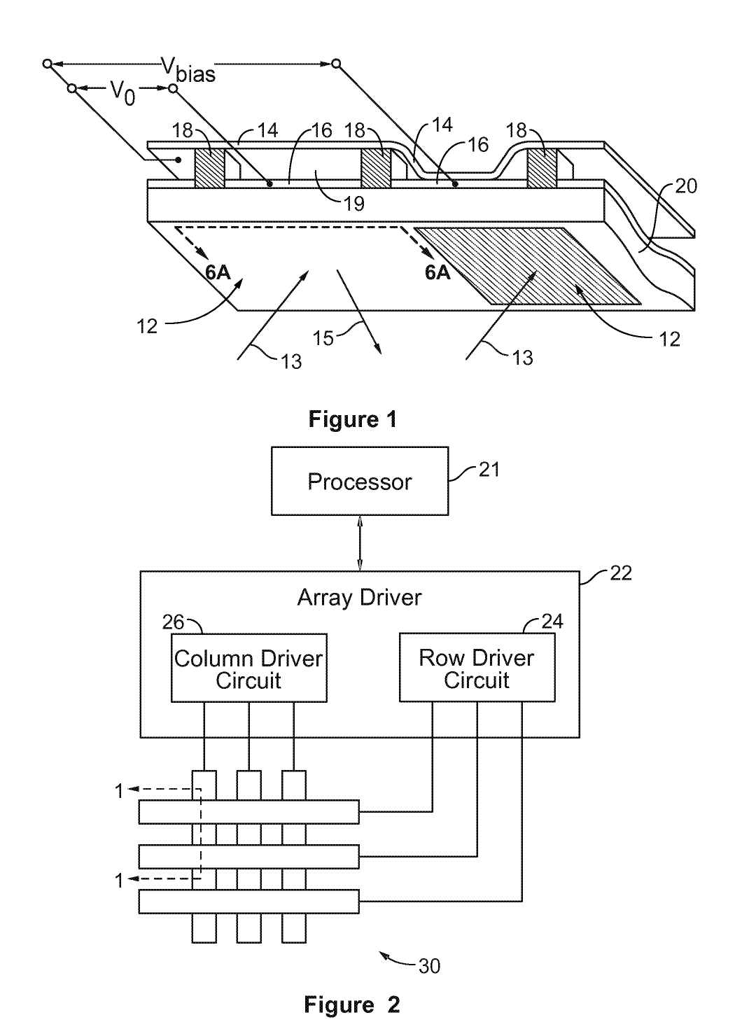

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

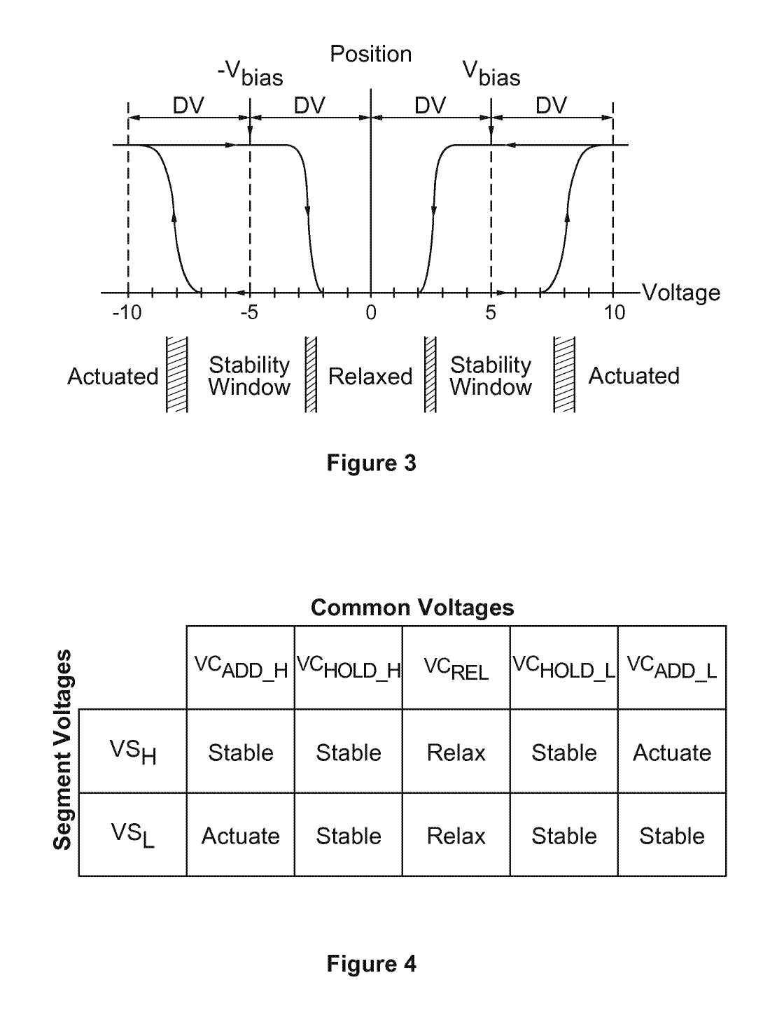

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

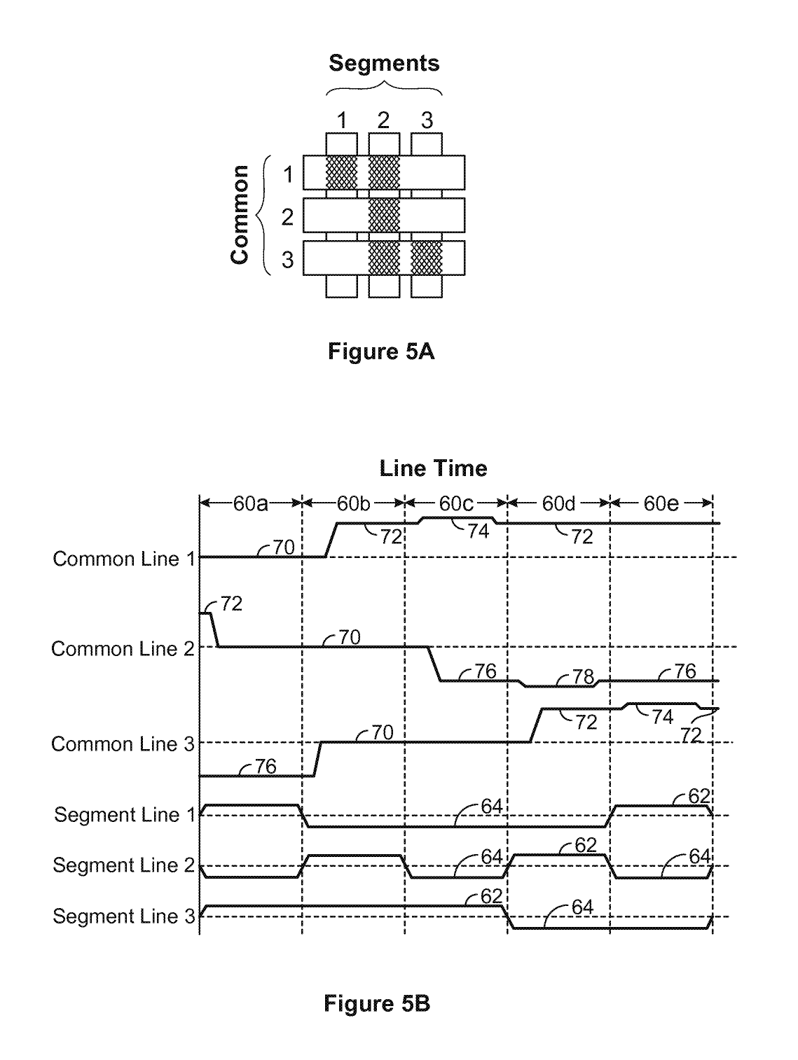

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

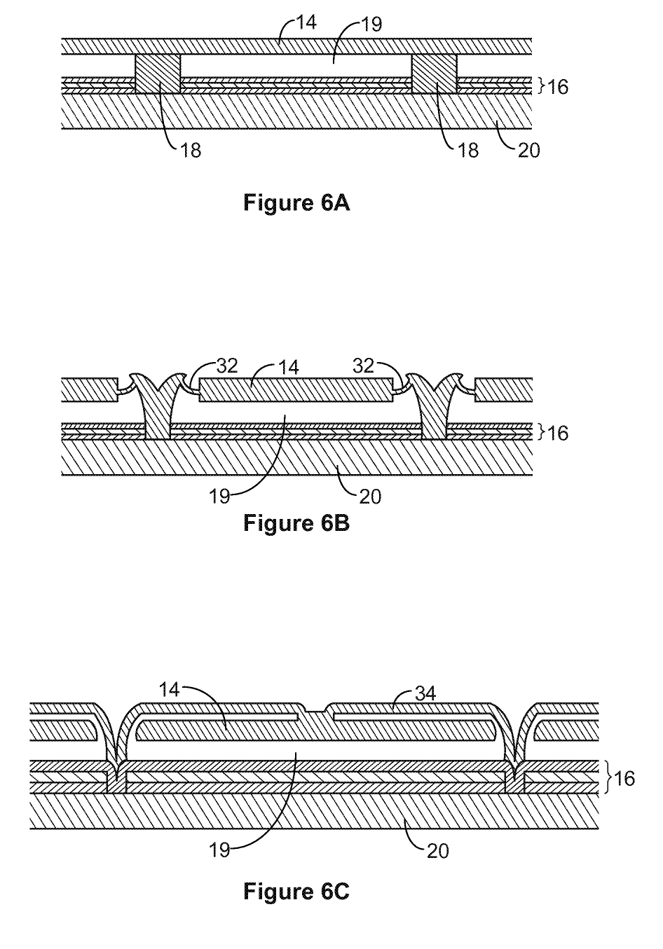

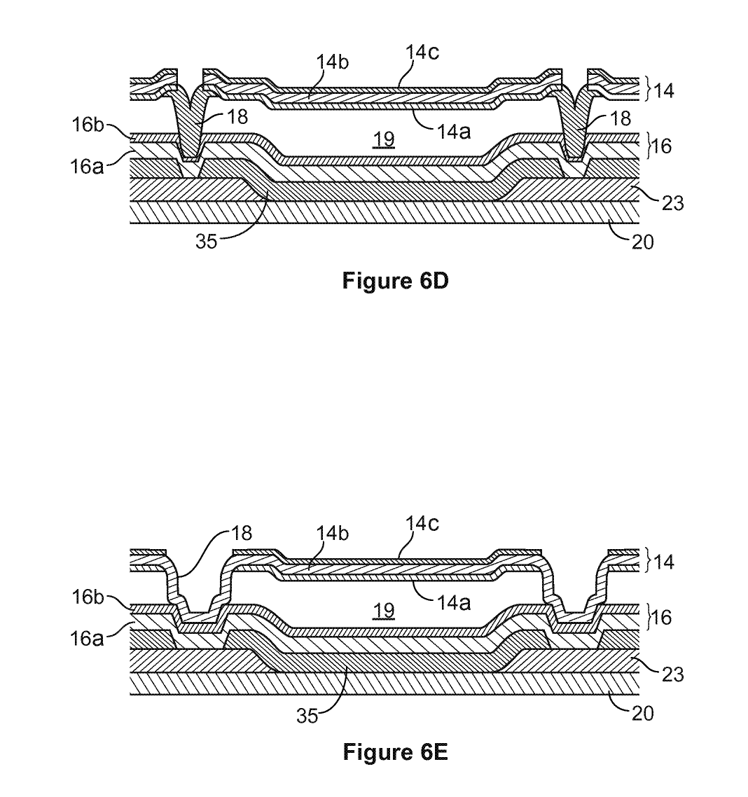

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CFO and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

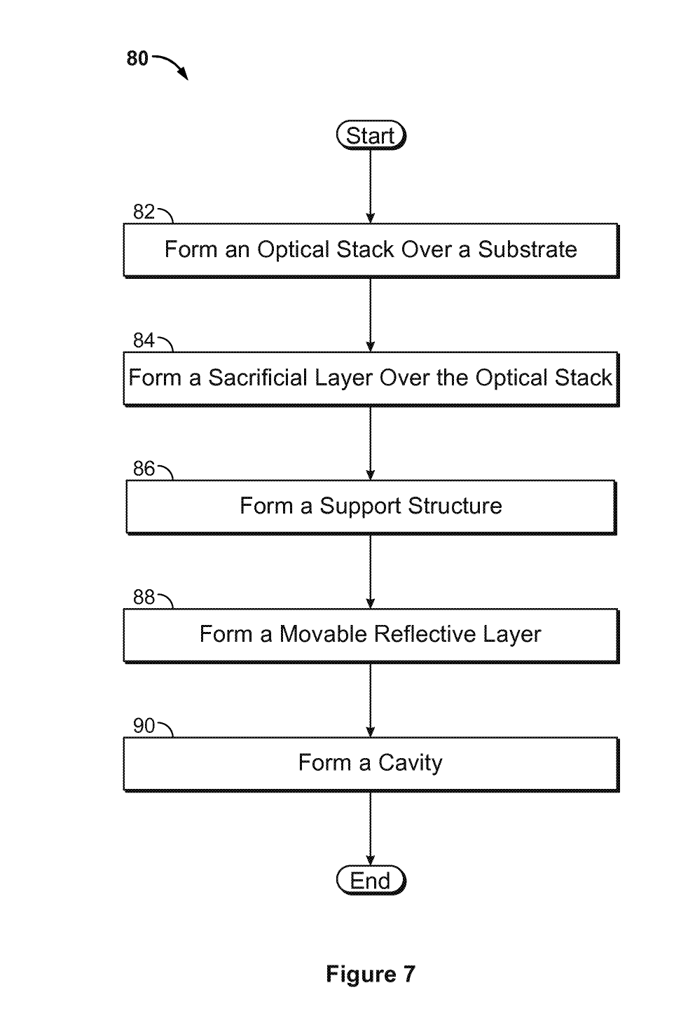

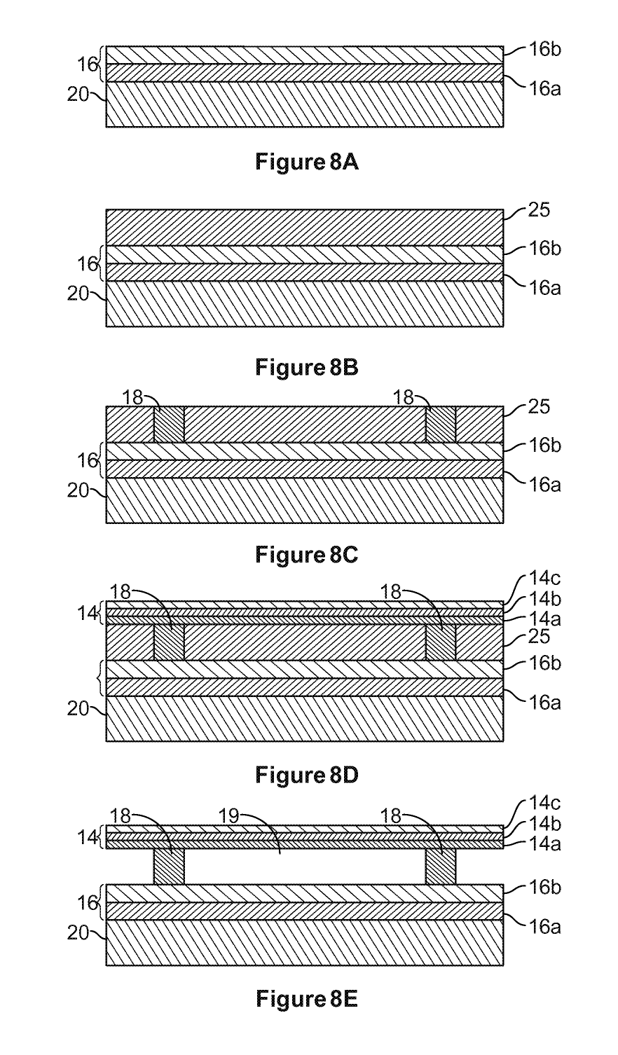

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning to remove portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Implementations described herein relate to substrate packaging of MEMS, including IMODs, and other devices. The transparent conductive vias described herein may be implemented for MEMS and non-MEMS devices, such as integrated circuits and optoelectronic devices. The methods and vias described herein are not limited to MEMS, integrated circuits, and optoelectronic devices, but may be applied in other contexts that employ a conductive pathway in a substrate.

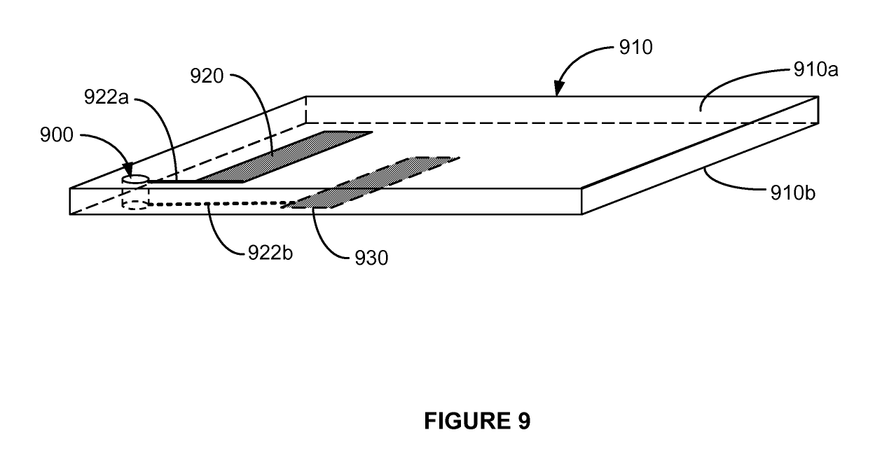

FIG. 9 shows an example of a perspective view of a transparent conductive via 900 in a transparent substrate 910. The transparent substrate 910 has a top surface 910a and a bottom surface 910b. As shown, a topside device 920 is formed or otherwise positioned on the top surface 910a, and a bottom side device 930 is formed or otherwise positioned on the bottom surface 910b. A topside conductor 922a, such as a patterned conductive routing line or electrical trace, connects the transparent conductive via 900 to the topside device 920. The topside conductor 922a and variants or similar structures discussed herein may thus provide means for conducting electricity on the top surface. A bottom side conductor 922b connects the transparent conductive via 900 to the bottom side device 930. The bottom side conductor 922b and variants or similar structures discussed herein may thus provide means for conducting electricity. The transparent conductive via 900 extends through the transparent substrate 910, providing a conductive pathway between opposing sides of the transparent substrate 910 and electrically connecting the topside device 920 and the bottom side device 930. The transparent conductive via 900 and variants or similar structures discussed herein may thus provide means for conducting electricity through the transparent substrate 910.

The topside and bottom side devices 920 and 930 can independently be one or more elements including, but not limited to, a contact pad, a bond pad, a thin film, a ground plane, a shield, an electrically passive or active element, a capacitor, an inductor, a resistor, a diode, a transistor, an integrated circuit, a sensor, an electronic device, a mechanical device, an electromechanical device, and a chip or die. The topside and bottom side devices 920 and 930 can be transparent or non-transparent. In some implementations, at least one of the topside device 920 and the bottom side device 930 is transparent.

The term “topside” is used herein to refer to a component such as a device or conductor that is disposed on or over the top surface 910a of the transparent substrate 910; the term “bottom side” is used herein to refer to a component such as a device or conductor that is disposed on or under the bottom surface 910b of the transparent substrate 910. In some implementations in which the transparent substrate 910 is configured to be part of a packaged device such as display device, the top surface 910a of the transparent substrate 910 can be a side of the transparent substrate 910 that is configured to face a viewer or user of the packaged device. In such implementations, the bottom surface 910b of the transparent substrate 910 can be configured to face away from the viewer or user. In some other implementations, a packaged device can be configured to be viewable or useable from both sides of the transparent substrate 910, with both the top surface 910a and bottom surface 910b of the transparent substrate 910 can be configured to face a viewer or user.

The topside and bottom side conductors 922a and 922b can be transparent or non-transparent. In some implementations, at least one of the top and bottom surfaces 910a and 910b of the transparent substrate 910 can include a transparent conductor, such as the topside conductor 922a or the bottom side conductor 922b, in electrical communication with the transparent conductive via 900. In some implementations, one or both of the topside and bottom side conductors 922a and 922b may include a small flange or ring that encircles the transparent conductive via 900. In some implementations, one or both of the topside and bottom side conductors 922a and 922b may include one or more conductive traces or routing lines that connect to and are in electrical communication with the transparent conductive via 900. In some implementations, one or both of the topside and bottom side conductors 922a and 922b can be part of or electrically connect to a contact pad, a bond pad, a thin film, a ground plane, a shield, an electrically passive element such as a capacitor, an inductor, or a resistor, or an active device such as a diode, a transistor, an integrated circuit, a sensor, an electronic device, a mechanical device, an electromechanical device, and a chip or die.

The transparent substrate 910 can be a generally planar substrate having substantially parallel top and bottom surfaces 910a and 910b. The transparent substrate 910 can be made of glass, plastic, or other substantially transparent material. In some implementations, the transparent substrate 910 may consist essentially of or include a spin-on dielectric material, such as solidified spin-on glass material. In some implementations, the transparent substrate 910 can include an epoxy, such as a UV curable or thermally curable epoxy that is flowable when dispensed. In some implementations, the transparent substrate 910 can include a borosilicate glass, a soda lime glass, quartz, Pyrex, or other suitable glass material.

In some implementations, the thickness of the transparent substrate 910 can be between about 10 microns and about 700 microns. The substrate thickness may vary according to the implementation. For example, in certain implementations where the transparent substrate 910 is a MEMS device substrate that is to be further packaged, the thickness may be between about 10 microns and about 300 microns, such as between about 50 microns and about 300 microns. Where the transparent substrate 910 includes surface mount device (SMD) pads and is configured to mount onto a printed circuit board (PCB), the thickness may be at least about 300 microns, such as between about 300 microns and about 500 microns. In some implementations, the transparent substrate 910 can include one or more glass substrates or panels and can have a thickness of 700 microns or more.

As indicated above, the transparent conductive via 900 can provide a conductive pathway between portions of the top surface 910a and the bottom surface 910b through the transparent substrate 910. In some implementations, the top surface 910a and/or the bottom surface 910b can be substantially planar. In some implementations, the top and/or bottom surface 910a and 910b can include various recessed or raised features (not shown) to accommodate, for example, a MEMS device or component thereof, an optoelectronic device, an integrated circuit, a display, or other device.

The transparent conductive via 900 can be optically transparent to visible light. In some implementations, the via 900 may be optically transparent but not transmissive to all light in the visible light spectrum. For example, the via 900 can have a tint of color or at least partially absorb light. Accordingly, the via 900 can be optically transparent when it transmits at least about 10% of light in the visible light spectrum. In some implementations, the via 900 can be optically transparent when it transmits at least about 50% of light in the visible light spectrum. In some implementations, the via 900 can be optically transparent when it transmits at least about 90% of light in the visible light spectrum. Other components described herein, such as substrates, contact pads, routing lines, various devices, and other deposited or otherwise disposed layers on the substrate can also be optically transparent and be transmissive to at least about 10%, 50%, or 90% of light in the visible light spectrum.

The transparent conductive via 900 can also be electrically conductive. In some implementations, the transparent conductive via 900 can have an electrical resistance between about 10 ohms and about 10,000 ohms. In some implementations, the via 900 can have an electrical resistance between about 10 ohms and about 100 ohms. In some implementations, the transparent conductive via 900 can have an electrical resistance below 10 ohms, such as between about 1 ohm and 10 ohms.

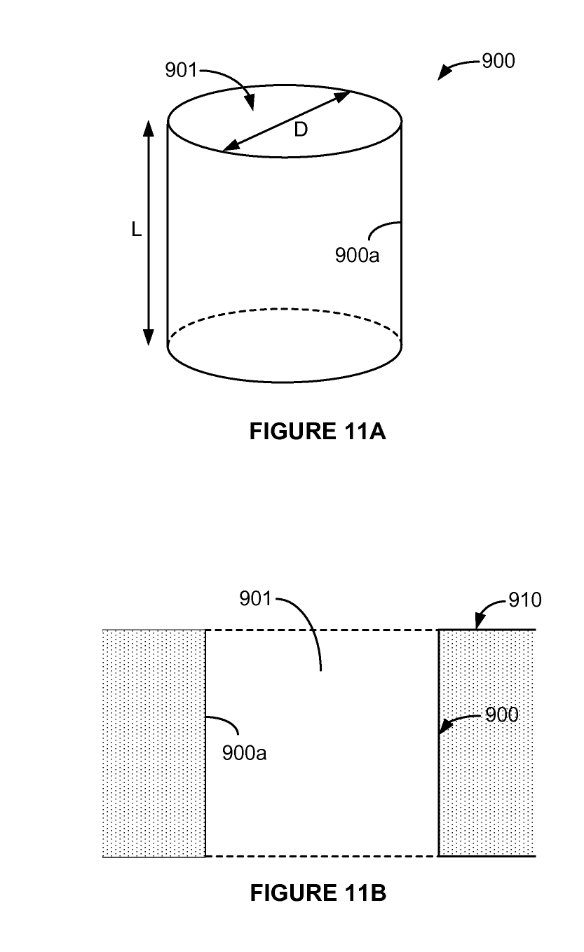

Electrical resistance (R) of the transparent conductive via 900 can be expressed in the equation R=ρL/A, where ρ represents the resistivity of the via material, L represents the length or height of the transparent conductive via 900, and A represents the cross-sectional area of the transparent conductive via 900 perpendicular to a longitudinal axis of the transparent conductive via 900. (A transparent conductive via 900 having a diameter D and a length L is depicted in FIG. 11A, discussed below.) Accordingly, the electrical resistance can be decreased by optimizing the aspect ratio between the height L and the diameter D of the transparent conductive via 900. Even when the aspect ratio is optimized, the electrical resistance can be limited by the resistivity. Transparent conductive vias generally have a higher resistivity than non-transparent conductive vias. Hence, transparent conductive vias 900 generally have a higher electrical resistance than non-transparent conductive vias that use, for example, a plated metal fill.

Transparent conductive vias filled with a transparent conductive material generally have a lower resistance than vias coated with a relatively thin layer of transparent conductive material on the interior surfaces or sidewalls of the via hole. Yet even vias that have a conductive material coating only the sidewalls can have sufficiently low resistance for implementations described herein. The resistance of a sidewall-coated via can be estimated from the aspect ratio of the via hole and the sheet resistivity of the coating material, by multiplying the aspect ratio by the sheet resistivity and dividing by pi for a nominally round via hole. Therefore, for example, a transparent conductive via with a height to diameter (aspect) ratio of 3:1 can have a resistance of roughly about one square for a conductive film deposited on the sidewalls. For example, a transparent conductive layer that has a sheet resistivity of fifty ohms per square when coating the interior surfaces of a via hole with an aspect ratio of 3:1 will have a resistance of about fifty ohms. ITO may have a sheet resistivity, for example, between about 30 and 100 ohms per square for films that are between about 50 and 100 nm thick. Conducting polymer systems such as poly(3,4-ethylenedioxythiophene):poly(styrenesulfonate) (PEDOT:PSS) may have a sheet resistivity between about 100 and 200 ohms per square.

A transparent conducting polymer containing carbon nanotubes may have a sheet resistivity between about 100 and 600 ohms per square. A via hole with a transparent conductive material coating the interior sidewalls may be filled with a non-conductive transparent material or a conductive transparent material. The latter can reduce the via resistance.

In some implementations, the interior sidewalls of a via hole in a transparent substrate may be coated with a relatively thin layer (for example, less than about 4000 Å) of doped polysilicon to form a transparent conductive via. Thin layers of polysilicon are partially transparent in the visible light range. In some implementations, the interior sidewalls of a via hole may be coated with a thin metal layer and optionally plated while retaining sufficient average transparency to the human eye. In an implementations with a thin metal layer coating the interior sidewalls of a via, the via may then be filled with a transparent conductive material.

The transparent conductive via 900 in FIG. 9 can have any appropriate height. In the example of FIG. 9, the transparent conductive via 900 extends through the substrate 910 and has a height about equal to the thickness of the substrate 910. In some implementations, a transparent conductive via extends only partially through a substrate and has a height less than the substrate thickness. For example, a transparent conductive via can have a height ranging from about 0.01 to about 0.09 times the substrate thickness. Partially through transparent conductive vias can be used, for example, to connect one or more layers of conductive materials separated by non-conductive layers. For example, a partially through transparent conductive via can connect a conductive layer on a top or bottom surface of a transparent substrate to a transparent layer embedded within the transparent substrate. Examples of such transparent conductive vias are discussed below with respect to FIG. 19.

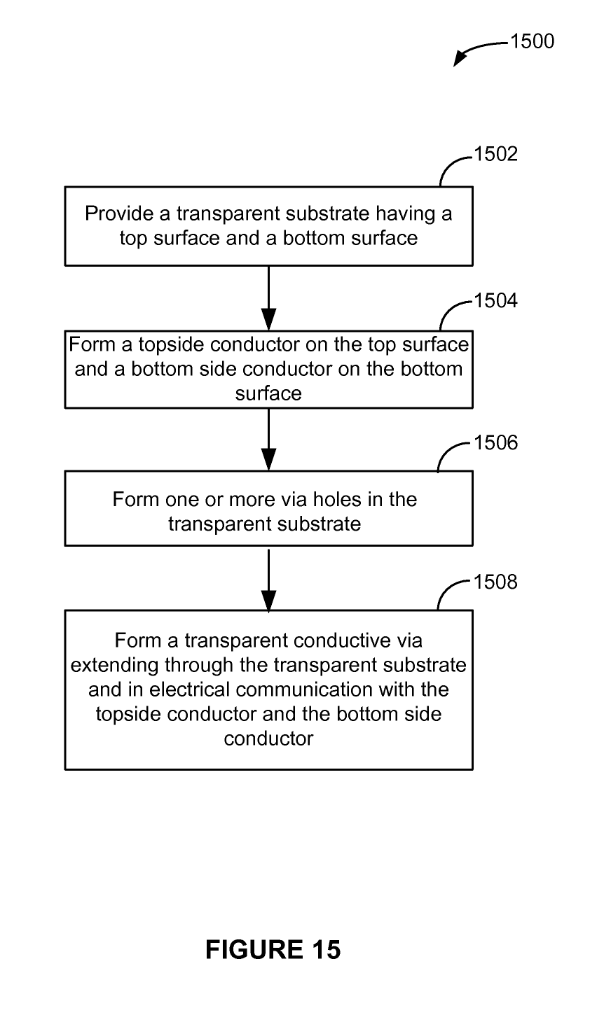

The transparent conductive via 900 in the example of FIG. 9 can also have any appropriate diameter. In some implementations, the diameter of the transparent conductive via 900 can depend in part on the method used to form the via hole. Methods of forming via holes are described in further detail below with reference to FIG. 15. The diameter of the transparent conductive via 900 can also depend in part on the height of the transparent conductive via 900 so as to achieve a certain aspect ratio between the height and the diameter of the transparent conductive via 900. In some implementations, the diameter of the transparent conductive via 900 can be between about 3 microns and about 700 microns, for example between about 3 microns and 10 microns. Aspect ratios for transparent conductive vias may vary from about 1:1 to over 30:1. In some implementations, the aspect ratio of a transparent conductive via is between 1:1 and 3:1. In some implementations, the aspect ratio of a transparent conductive via is between 3:1 and 10:1.

The transparent conductive via 900 can also have any appropriate shape. For example, in certain implementations, via openings for the transparent conductive via 900 can be circular, semi-circular, oval, rectangular, polygonal, rectangular with rounded edges, polygonal sharp edges, slotted, or otherwise shaped. In some implementations, the transparent conductive via 900 can have linear or curved sidewall contours.

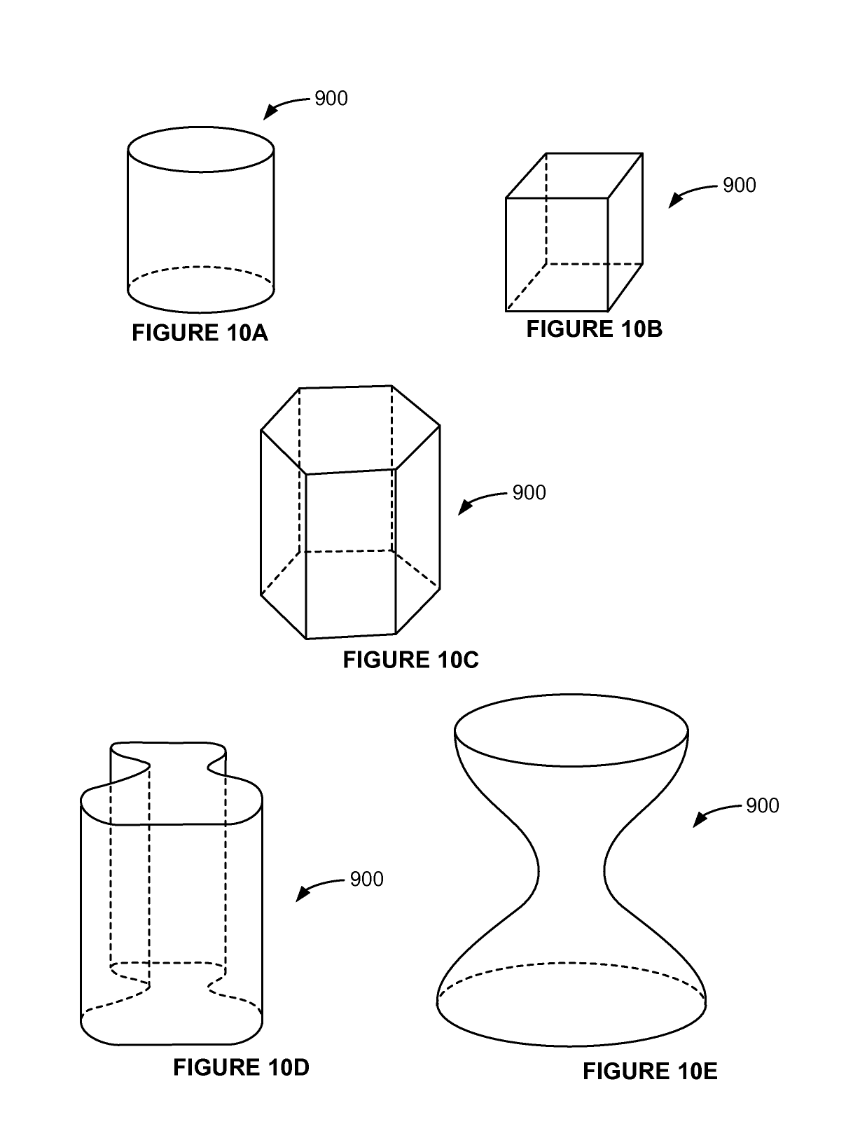

FIGS. 10A-10E show examples of schematic illustrations of transparent conductive vias having various shapes. FIG. 10A shows an example of a transparent conductive via 900 with a circular opening and a linear sidewall contour. FIG. 10B shows an example of a transparent conductive via 900 with a rectangular opening and a linear sidewall contour. FIG. 10C shows an example of a transparent conductive via 900 with a polygonal opening and a linear sidewall contour. FIG. 10D shows an example of a transparent conductive via 900 with a curvilinear-shaped opening and a linear sidewall contour. While the sidewalls of the transparent conductive vias 900 shown in the examples of FIGS. 10A-10D are nominally straight, in some other implementations, the sidewalls of the transparent conductive via 900 may be tapered inward or outward from one surface or the other, tapered from each surface, slightly curved, or otherwise contoured. The aspect ratio of the transparent conductive via 900 may be close to 1:1 as shown. Alternatively, the aspect ratio may vary from about 1:1 to 30:1 or higher. FIG. 10E shows an example of a transparent conductive via 900 with a circular opening and a curved, dual-concave contour, with the opening on one end slightly larger than the opening on the other end.

FIG. 11A shows an example of a schematic illustration of a through-substrate via hole for a transparent conductive via 900. The via hole 901, which can be formed by a number of methods such as those described in further detail below with respect to FIG. 15, can have a length L and a diameter D. Furthermore, the via hole 901 can have a sidewall or interior surface 900a. FIG. 11B shows an example of a cross-sectional schematic illustration of the through-substrate via hole of FIG. 11A. As illustrated in the example of FIG. 11B, the via hole 901 extends through a transparent substrate 910. In some implementations, the via hole 901 can be empty or air-filled. In some implementations, the via hole 901 can be wholly or partially filled with a conductive or non-conductive transparent material. In some implementations, the interior surface 900a can be coated with a conductive coating material. In some implementations, a non-conductive material such as silicon dioxide or silicon nitride may be deposited on the sidewall or interior surface 900a of via hole 901, then coated with a transparent conductive material. A non-conductive coating (not shown) may provide improved adhesion of subsequent layers, and may provide other benefits such as improved electrical isolation, smoothing of the interior surfaces 900a, or optical index matching between the transparent conductive material and the transparent substrate.

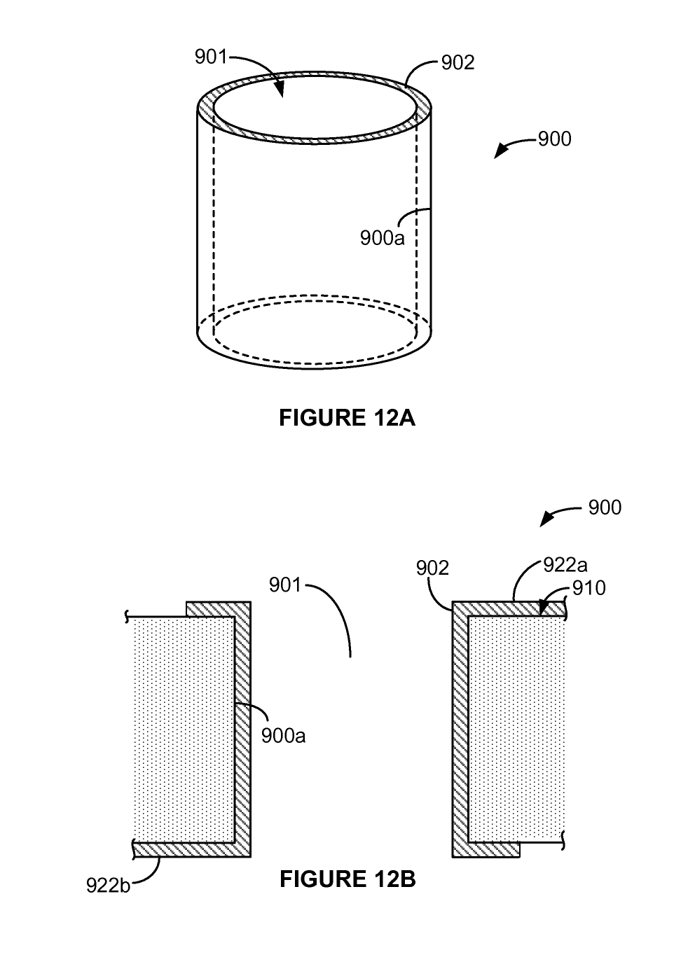

FIG. 12A shows an example of a schematic illustration of a through-substrate transparent conductive via with a coating material. As illustrated in the example of FIG. 12A, a coating material 902 can coat a sidewall or interior surface 900a of the via hole 901. (For ease of illustration, only the top surface of the coating material 902 is shown with hatching.) In some implementations, the coating material 902 can include one or more transparent conductive materials. In some implementations, the coating material 902 can include a transparent conductive oxide. For example, the coating material 902 can include indium tin oxide (ITO) or aluminum zinc oxide (AZO). In some implementations, the coating material 902 can include a transparent conductive polymer. For example, the coating material 902 can include at least one of polyaniline, polypyrrole, a polythiophene such as poly(3,4-ethylenedioxythiophene), or any other inherently conductive or semiconductive polymer. In some implementations, the coating material 902 can include a transparent conductive ink. Examples of transparent conductive inks include ClearOhm™ from Cambrios Technologies. The coating material 902 may be deposited on the interior surface 900a by any of a number of methods described in further detail below with respect to FIG. 15.

FIG. 12B shows an example of a cross-sectional schematic illustration of the through-substrate transparent conductive via with a coating material of FIG. 12A. The transparent conductive via 900 extends through a transparent substrate 910. In addition to coating the interior surface 900a of the via hole 901, the coating material 902 can be formed on one or both of the top and bottom surfaces of the transparent substrate 910, at least in a portion of the top or bottom surface surrounding the via hole 901. The coating material 902 that is formed on the top and/or bottom surface of the transparent substrate 910 may be patterned and etched in some implementations to form routing lines and/or contact pads. For example, the coating material 902 may be patterned and etched on the top surface and the bottom surface of the transparent substrate 910 to form conductive features such as a flange surrounding the via or to form conductors such as connective traces on one or both sides of the substrate 910 that connect to the via 900. In the example of FIG. 12B, a patterned topside conductor 922a and a patterned bottom side conductor 922b are depicted.

The coating material 902 along the interior surface 900a of the via hole 901 can have a thickness that balances the performance of electrical conductivity and optical transparency. For example, in certain implementations, if the coating material 902 increases in thickness then the optical transparency can decrease. In certain implementations, if the coating material 902 decreases in thickness then the electrical resistance of the via can increase. Accordingly, the coating material 902 can have a thickness that provides both sufficient electrical conductivity and sufficient optical transparency. In some implementations, the coating material 902 can be between about 50 Å and about 3000 Å, or between about 100 Å and about 2000 Å. The thickness of the coating material 902 can also depend at least in part on the material. Example thicknesses of transparent conductive polymers can range from about 100 Å to two microns or more. Example thicknesses of transparent conductive oxides can range from about 100 Å to about 2000 Å.

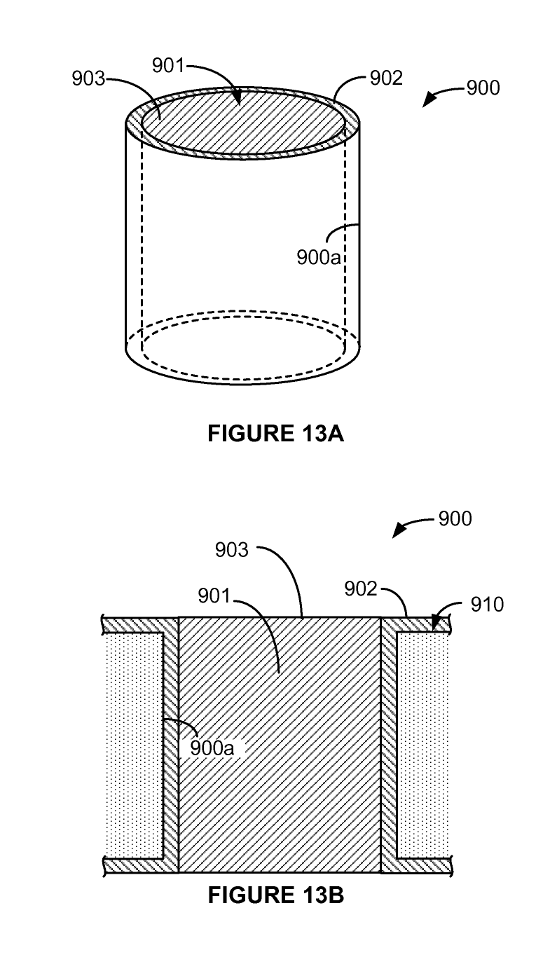

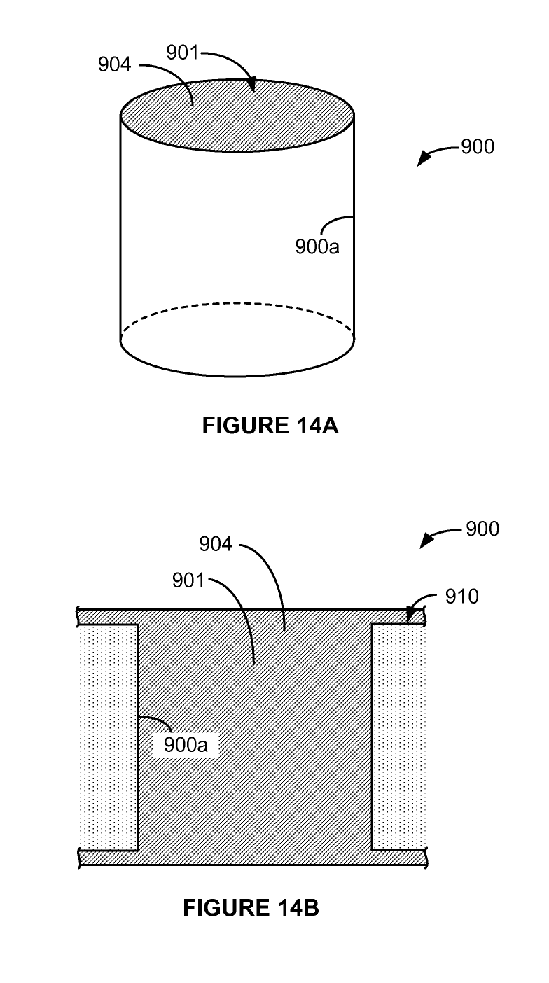

FIG. 13A shows an example of a through-substrate transparent conductive via with a coating material and a filler material. As illustrated in the example of FIG. 13A, the coating material 902 coats and surrounds the interior surface 900a of the via hole 901, and the filler material 903 can fill the remainder of the via hole 901. (For ease of illustration, only the top surfaces of the coating material 902 and the filler material 903 are shown with hatching.) According to various implementations, the filler material 903 can include a transparent conductive or non-conductive material. In some implementations, the filler material 903 can include an electrically conductive or non-conductive polymer with desirable optical properties. Examples can include silicone, poly(methyl methacrylate) (PMMA), and polycarbonate. In some implementations, the coating material 902 can be the same as the filler material 903. In some implementations, the coating material 902 can be different from the filler material 903. Further examples of conductive filler materials are given below with respect to FIG. 14A. The filler material 903 may be deposited in the via hole 901 by any of a number of methods described in further detail below with reference to FIG. 15.

FIG. 13B shows an example of a cross-sectional schematic illustration of the through-substrate transparent conductive via with a coating material and a filler material of FIG. 13A. In some implementations, the filler material 903 may reduce the stress on the deposited thin film of the coating material 902. In some implementations, the filler material 903 may seal the via hole 901 and limit the ingress of liquids or gases through the via hole 901. In some implementations, the filler material 903 may serve as a thermally conductive path to transfer heat from devices mounted on one side of the transparent substrate 910 to the other.

FIG. 14A shows an example of a schematic illustration of a through-substrate transparent conductive via with a conductive filler material. As illustrated in the example of FIG. 14A, the filler material 904 can completely fill the via hole 901 and directly contact the interior surface 900a. (For ease of illustration, only the top surface of the filler material 904 is shown with hatching.) The filler material 904 can be a transparent conductive material, with examples including a transparent conductive polymer, a nanotube-filled resin, a metal nanowire-filled resin, a particle-filled resin, a metal particle-filled resin, a polyelectrolyte, a polymer gel electrolyte, a bicontinuous phase-separated blend of different transparent conductive polymers, a bicontinuous phase-separated blend of a transparent conductive polymer and a transparent non-conductive polymer, a microphase-separated block copolymer including transparent conductive blocks, and a microphase-separated block copolymer including transparent conductive and transparent non-conductive blocks. Examples of transparent conductive polymers that can be co-monomers of a block copolymer filler material or in a bicontinuous phase-separated blend filler material include polyanilines, polypyrroles, and polythiophenes. Examples of transparent non-conductive polymers that can be co-monomers of a block copolymer filler material or in a bicontinuous phase-separated blend filler material include polybutadiene, polyisoprene, polystyrene, poly(n-alkyl acrylates), and poly(n-alkyl methacrylates).

FIG. 14B shows an example of a cross-sectional schematic illustration of the transparent through-substrate via with a filler material of FIG. 14A. The filler material 904 can fill the via hole 901 and can be formed along the interior surface 900a of the via hole 901. The filler material 904 can also be formed on one or both of the top and bottom surfaces of the transparent substrate 910, or at least in a portion of the area surrounding the via hole 901. The filler material 904 may be deposited in the via hole 901 by any of a number of methods described in further detail below with reference to FIG. 15.

FIG. 15 shows an example of a flow diagram illustrating a method of manufacturing a transparent conductive via. The process 1500 begins at block 1502 where a transparent substrate having a top surface and a bottom surface is provided. The transparent substrate can be made of glass, plastic, or other transparent material, as discussed above. In some implementations, block 1502 can include providing one or more sheets or plates of glass. In some implementations, block 1502 can include solidifying one or more layers of a flowable transparent material on a base or a carrier substrate, which may also be transparent. Examples of flowable transparent materials can include spin on dielectric and epoxy materials.

The process 1500 continues at block 1504 where a topside conductor on the top surface and a bottom side conductor on the bottom surface are formed. As discussed above, the topside and bottom side conductors, when patterned, can include but are not limited to electrical traces, electrical interconnects, contact pads and bond pads, and electrically passive or active elements such as capacitors, inductors, resistors, sensors, chips, transistors and diodes. The topside and bottom side conductors can be in electrical contact with MEMS devices and/or integrated circuit devices. The topside and bottom side conductors can be transparent or non-transparent.

In some implementations, forming the topside and/or bottom side conductors can involve depositing an electrically conductive seed layer on the top and/or bottom surface of the substrate. This can involve any deposition process including but not limited to PVD, CVD, atomic layer deposition (ALD), and evaporation. The electrically conductive material can include a metal, polymer, or other electrically conductive material. Example metals that can be deposited include but are not limited to copper (Cu), gold (Au), nickel (Ni), palladium (Pd), and combinations and alloys thereof.

A resist can be patterned on the electrically conductive seed layer. In some implementations, an electrophoretic resist (EPR) can be used. In some implementations, other types of resists may be used, such as sprayed liquid photoresists and dry film resists. The process can continue by depositing or plating the exposed electrically conductive seed layer to form the conductor. In some implementations, conductive routing can also be formed by depositing or plating the exposed electrically conductive seed layer. Examples of plated metal material can include Cu, Cu/Ni/Au trilayers, Cu/Ni/Pd/Au trilayers, Ni/Au bilayers, Ni/Pd/Au trilayers, Ni alloy/Pd/Au trilayers, and Ni alloy/Au bilayers. The process can continue with removal of the resist by exposing the resist to an appropriate solvent and etching the remaining electrically conductive seed layer to electrically isolate the plated material.

In some implementations, the topside and/or bottom side conductors can be formed without electroplating by a process that involves depositing the electrically conductive material of the conductor directly on the top or bottom surface of the substrate. This can involve any deposition process including but not limited to PVD, CVD, ALD, and evaporation. Examples of electrically conductive material that can be deposited can include non-transparent materials such as Al and other metals (although these materials can be patterned to form narrow traces that are essentially transparent to the human eye) as well as transparent materials such as transparent conductive oxides, transparent conductive polymers, and transparent conductive inks. The process can continue by patterning a resist on the electrically conductive material, such as an electrophoretic resist, a dry film resist or a sprayed liquid photoresist. The resist can serve to mask portions of the electrically conductive material that are to remain. The process can continue by etching the exposed electrically conductive material to form a patterned conductor on one or both sides of the substrate. In some implementations, a reactive ion etch (RIE) is used to etch electrically conductive material such as Al. The process can continue with removal of the resist.

In some implementations, the topside and/or bottom side conductors can be formed by screenprinting. For example, a transparent conductive ink can be screenprinted on the top and/or bottom surface to form electrical contacts and/or conductive routing. In some implementations, the conductors can be formed by a maskless direct writing process, such as dispensing or inkjet printing. In some implementations, a jet can be used to dispense an electrically conductive paste. After dispensing, the electrically conductive paste can be cured to form the conductor. In some implementations, a jet can be used to dispense an electrically conductive colloidal aerosol. After dispensing, the colloid can be sintered. In some implementations, a conductive transparent ink can be applied by inkjet printing.

Block 1504 can further include forming conductive routing on the top and/or bottom surface. Conductive routing can be formed from the same or different materials as the topside and bottom side conductors. Conductive routing can be formed using the same or different technique as used to form the topside and bottom side conductors. For example, in some implementations, transparent conductive routing may electrically connect a transparent conductive via to a non-transparent conductor. In some implementations, one or more deposition, pattern, and etch steps may be used to form electrical routing and devices on one or both sides of the substrate. For example, topside and/or bottom side conductors may be patterned to include a small flange or ring for encircling a transparent conductive via. In some implementations, patterned topside conductors and/or bottom side conductors may include one or more conductive traces or routing lines with associated crossovers and underpasses. In some implementations, patterned topside and bottom side conductors can be configured to be part of or to electrically connect to one or more devices or structures such as a contact pad, a bond pad, a thin film, a ground plane, a shield, an electrically passive element such as a capacitor, an inductor, or a resistor, or an active device such as a diode, a transistor, an integrated circuit, a sensor, an electronic device, a mechanical device, an electromechanical device, and a chip or die.

The process 1500 continues at block 1506 where one or more via holes are formed in the transparent substrate. Techniques for forming the one or more via holes can include laser ablation, sandblasting, drilling, wet etching, and dry etching. In some implementations, block 1506 can include patterning and etching of photo-sensitive glass. According to various implementations, a single-sided or double-sided process of forming a through-substrate via hole can be performed on the transparent substrate. A double-sided process involves forming two holes on opposite sides of the transparent substrate, and then joining the two holes to form the through-substrate via hole. The via holes can be dimensioned and shaped according to some of the implementations described earlier herein, such as in FIGS. 9 and 10A-10E.

In some implementations, the one or more via holes can be formed using a wet etching method. This method can begin with forming masks on one or both sides of the transparent substrate. Forming a mask can involve applying a photo-sensitive layer on the transparent substrate, exposing a pattern lithographically onto the photo-sensitive layer on the transparent substrate, and then developing the photo-sensitive layer. Alternatively, in some implementations, an etch-resistant layer deposited on the transparent substrate can be patterned and etched, and then serve as an etch mask. Mask materials may include photoresist, deposited layers of polysilicon or silicon nitride, silicon carbide, or thin metal layers of chrome, chrome and gold, or other etch-resistant material. The masks can be formed to correspond to the placement, size, and shape of the via holes. In some implementations, the masks are aligned on the top and bottom surfaces of the transparent substrate. This method can continue by placing the transparent substrate in a wet etch solution, such as solutions that include hydrogen fluoride, for example, concentrated hydrofluoric acid (HF), diluted HF (HF:H₂O), buffered HF (HF:NH₄F:H₂O), or other suitable etchant with a reasonably high etch rate of the transparent substrate and high etch selectivity for the substrate material compared to the masking material. The etchant may also be applied by spraying, puddling, or other appropriate technique.

In some implementations, the one or more via holes can be formed using a sandblasting method (also known as powder blasting). This method can begin by forming masks or stencil patterns on one or both sides of the transparent substrate. For sandblasting, mask materials can include photoresist, a laminated dry-resist film, a compliant polymer, a silicone rubber, a metal mask, or a metal or polymeric screen. The masks can be formed to correspond to the placement, size, and shape of the via holes. This method can continue by sandblasting either one or both sides of the transparent substrate. The sandblasting method can involve blasting particles of several microns or smaller at a high pressure. In some implementations, vias can be formed with a steep taper using a very high sandblast pressure. In some implementations, vias can be formed using varied sandblast pressures.

In some implementations, the one or more via holes can be formed using a dry etching method. This method involves exposing the masked substrate to a plasma, such as a fluorine-containing plasma. The plasma may be direct (in situ) or remote. Examples of plasmas that may be used include inductively-coupled or capacitively-coupled RF plasmas and microwave plasmas.

In some implementations, the one or more via holes can be formed using laser ablation (also known as laser drilling). By using a laser beam, vias can be formed by melting and evaporating targeted material without conventional photolithographic masks. Some types of lasers include, but are not limited to CO₂, YAG, Nd:YAG, quadrupled ND:YAG, and excimer lasers. In certain implementations, the excimer laser is used for precision tasks for drilling via holes while avoiding thermal effects of damage from heat affected zones. A stencil may be used in combination with the laser to ensure accurate alignment of the laser radiation within the desired area. Relative to sandblasting, laser ablation can achieve higher aspect ratios and smaller feature sizes.

In some implementations, the one or more vias can be formed using mechanical drilling, photo-patterning, or other methods of forming via holes as known in the art. The via holes may be formed using any combinations of the methods described above, such as sandblasting and wet etching, or laser ablation and wet etching.

The process 1500 continues at block 1508 where a transparent conductive via is formed extending through the transparent substrate and in electrical communication with the topside conductor and the bottom side conductor.

In some implementations, forming the transparent conductive via can include coating the via hole with an electrically conductive transparent material. FIGS. 12A and 12B show an example of a via hole coated with an electrically conductive transparent material. Coating and/or filling the via hole can involve one or more sputter deposition or other PVD process, a CVD process, an ALD process, an evaporation process, an injection process, a dispensing process, a squeegee process, or a spin-coat process. In some implementations, a transparent conductive oxide can be sputter-deposited on the interior surface of the via hole. In other implementations, a transparent conductive polymer can be coated on the interior surface of the via hole.

In some implementations, forming the transparent conductive via can further include filling the remainder of the via hole with electrically conductive or non-conductive transparent material. FIGS. 13A and 13B show an example of a via hole coated with an electrically conductive transparent material and filled with an electrically conductive or non-conductive transparent material. Filling the via hole can involve one or more sputter depositions or other PVD processes, a CVD process, an ALD process, an evaporation process, an injection process, a dispensing process, a squeegee process, or a spin-coat process. For example, a bicontinuous phase-separated blend of a conductive polymer and a non-conductive polymer can be deposited by spin-coating.

In some implementations, forming the transparent conductive via can include filling the via hole with an electrically conductive transparent material. FIGS. 14A and 14B illustrate an example of a via hole filled with an electrically conductive transparent material. Filling the via hole can involve any one or more of the deposition methods described above.

In some implementations, the process 1500 can further include one or more operations of attaching multiple transparent substrates or multiple layers of a transparent substrate together to form a multilayer transparent substrate including one or more conductors such as electrical contacts, pads and/or conductive routing embedded within the multilayer transparent substrate. An example of such a transparent substrate is provided below with respect to FIG. 19.

Blocks 1502-1508 can be performed in any appropriate sequence. For example, in some implementations in which the transparent substrate includes a multi-layered stack, one or more operations of block 1504 can be performed prior to block 1502. That is, block 1502 can include providing a multi-layered stack, with block 1504 including forming a topside or bottom side conductor on one layer, prior to or during assembly of the stack. In one such example, a conductor such as conductive routing can be formed on a base or a carrier substrate (for example, as part of block 1504) prior to depositing and solidifying a flowable transparent material on the conductive routing (for example, as part of block 1502). In some implementations, the base or carrier substrate can form a layer of the transparent substrate. In some other implementations, the base or carrier substrate can be detached from the conductors on the solidified flowable transparent material.

In some implementations, one or more operations of block 1506 can be performed prior to one or more operations of block 1504. Furthermore, one or more operations of block 1508 can be performed prior to or during one or more operations of block 1504 after via holes are formed (for example, as part of block 1506). For example, in some implementations, a transparent conductive ink may be simultaneously dispensed in a via hole (for example, as part of block 1508) and on the top and/or bottom surface of the transparent substrate (for example, as part of block 1504). In some implementations, the transparent conductive material may be deposited on the sidewall of the via hole and simultaneously on the top or bottom surface of the substrate, then patterned on the top and/or bottom side to form patterned conductors. In some implementations, the deposited material on the sidewalls may cover and make electrical contact to electrical traces and other structures already formed on the substrate. In some implementations, one or more patterning operations may be performed on the top and/or bottom surface of the transparent substrate after one or more via holes are formed. A photoresist that tents over the via holes may be used in such patterning operations. This is so that after resist patterning, the via holes are substantially free of resist and resist-related residue. One example of such a resist is DuPont® MX5000 dry film photoresist, which can be applied to the substrate surface by lamination. In some implementations, multiple substrates can be processed as described in FIG. 15, with topside conductors and bottom side conductors formed on the surfaces of each of the multiple substrates at various locations and one or more transparent conductive vias extending through each of the multiple substrates to electrically connect the topside and bottom side conductors. Then, the multiple substrates may be laminated together to form a multi-layered substrate, where the entire multi-layered substrate has topside and bottom side conductors as well as conductors embedded in the multi-layered substrate. Alternatively, process 1500 can be performed on a substrate. Then, another layer may be formed over the substrate after block 1508, for example by forming a spin-on dielectric layer over the substrate. One or more operations of process 1500 may be performed on the spun-on layer to then provide a multi-layered substrate.

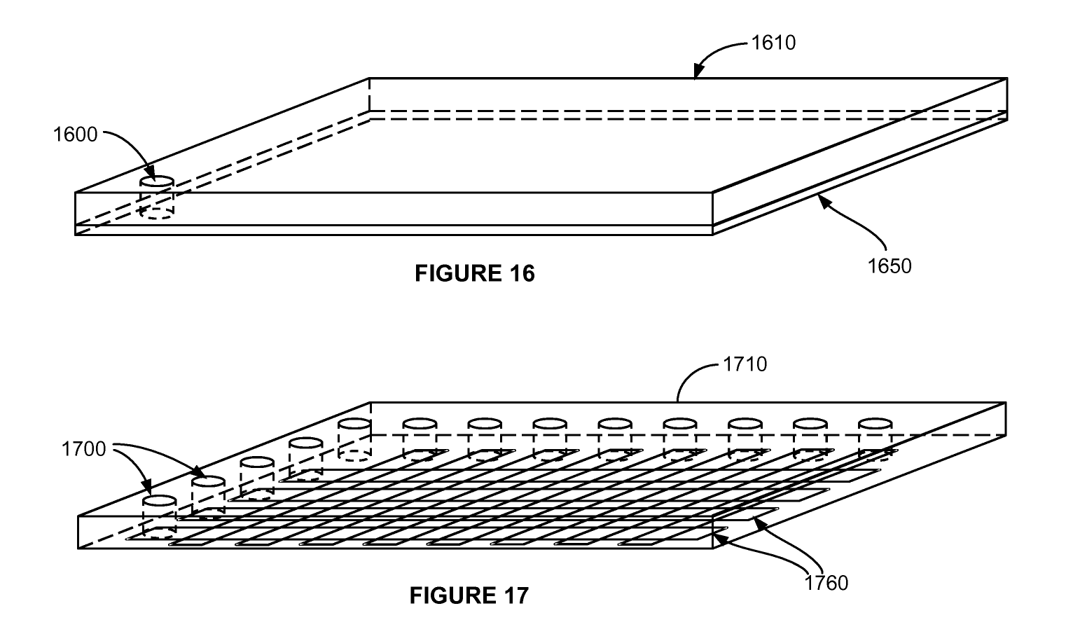

FIG. 16 shows an example of a perspective view of a transparent conductive via in electrical connection with a ground plane. The transparent conductive via 1600 can allow simple electrical connections from one side of the transparent substrate 1610 to the ground plane 1650 formed on the other side of the transparent substrate 1610. The ground plane 1650 may be formed from a thin layer of transparent conductive material. In some implementations, the ground plane or portions thereof may be formed from a fine grid of essentially or substantially transparent narrow metal traces or traces formed from a black mask structure as described above. In some implementations, transparent or non-transparent electrical conductors or routing (not shown) on the top side of the transparent substrate 1610 can connect to the ground plane 1650 through the transparent conductive via 1600. The ground plane 1650 can serve to limit static buildup of electricity or for other purposes such as electrical shielding. In some implementations, the ground plane 1650 can be a cover plate of an IMOD. In some implementations, the ground plane 1650 can be a negative terminal of a battery.

FIG. 17 shows an example of a perspective view of an array of transparent conductive vias in electrical connection with touch sensor electrodes. A high density of transparent conductive vias 1700 arranged in an array (shown here near the periphery) can allow large-scale connectivity between electrodes or devices on one side of a transparent substrate 1710 and devices on the other side. The array of transparent conductive vias 1700 can provide an electrical connection to one or more integrated circuits or optoelectronic or MEMS devices. In the example of FIG. 17, the array of transparent conductive vias 1700 can provide an electrical connection between touch sensor electrodes 1760 on one side and electrical connectors and/or integrated circuits (not shown) on the other side of the transparent substrate 1710. In some implementations, the touch sensor electrodes 1760 can be part of a touch sensor input device for an electronic device incorporating a display. A touch sensor input device can be in electrical communication with a processor of the electronic device through the transparent conductive via.

The array of transparent conductive vias 1700 can serve to reduce the package size of touch sensor devices. In some implementations, the pitch between vias 1700 can be between about 50 microns and about 5,000 microns. In some implementations, the thickness of the transparent substrate 1710 can be between about 300 microns and about 500 microns. In some implementations where the touch sensor electrodes 1760 are coupled with a display, the front or backside of the transparent substrate 1710 can include flex tape interconnections and routing to provide external electrical connections.

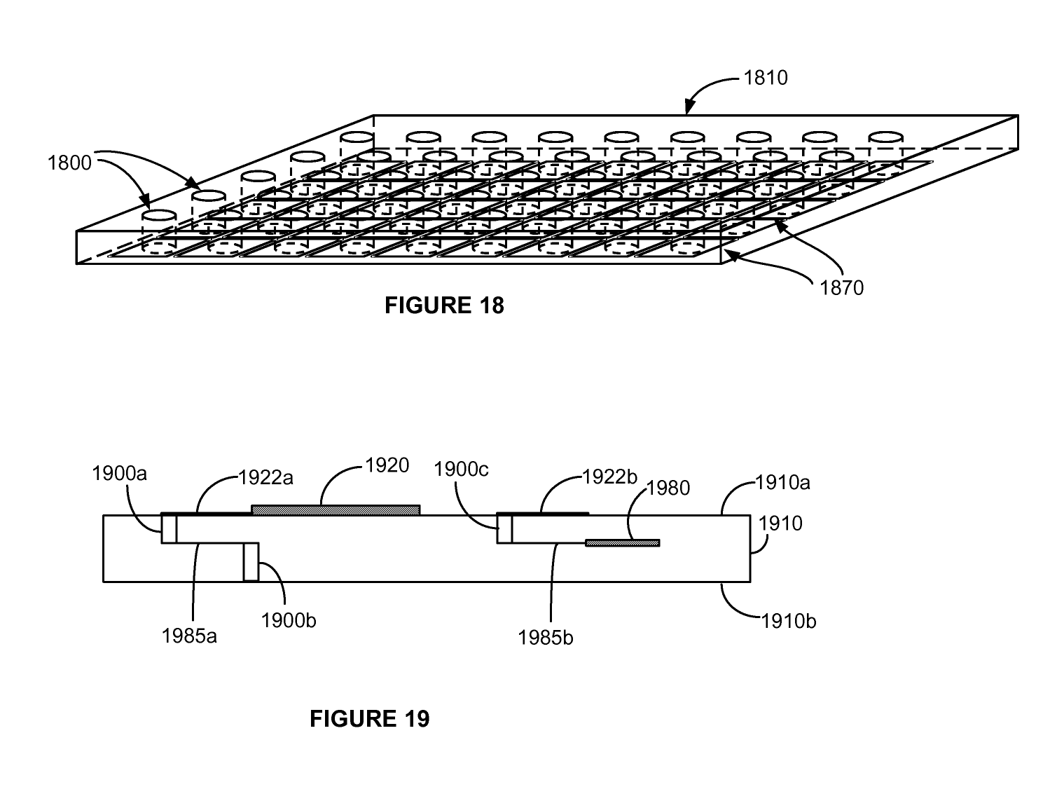

FIG. 18 shows an example of a perspective view of an array (shown here as a two-dimensional array) of transparent conductive vias in electrical connection with reflective display devices. In some implementations, the reflective display devices 1870 can be an array of pixels that can each produce color from one or more IMOD display elements. The array of transparent conductive vias 1800 can provide an electrical connection between the IMOD display elements on one side and electrical connectors, for example, ITO routing (not shown), on the other side of the transparent substrate 1810. In some implementations, the pitch between vias 1800 can be between about 50 microns and about 150 microns, or about one to two transparent conductive vias 1800 per pixel. In some implementations, an array of transparent conductive vias 1800 can provide electrical connections to reflective, transflective or transmissive display elements on the opposite side of the substrate, or alternatively to an optoelectronic device, an integrated circuit, a MEMS device, a sensor, or other device. In some implementations, one or more of the transparent conductive vias 1800 can be in electrical communication with a processor, driver circuit, or other component of an electronic device incorporating a display, for example as described above with respect to FIG. 2.

In some implementations, transparent conductive vias can electrically connect conductors such as conductive traces or routing through different layers on one or more sides of a transparent substrate. The transparent conductive vias can be in electrical communication with conductive routing and other conductive features positioned between one or more layers of a transparent substrate. FIG. 19 shows an example of a cross-sectional schematic illustration of a multilayer transparent substrate including a plurality of transparent conductive vias. In the example of FIG. 19, transparent conductive vias 1900a-1900c extend partially through the transparent substrate 1910 and can provide electrical connection to one or more “buried” devices or structures 1980 through conductive routing 1985a and 1985b positioned within the transparent substrate 1910. Transparent conductive vias 1900a-1900c that extend only partially through the substrate 1910 can be referred to as “blind” or “partially through” vias.

The transparent substrate 1910 includes a top surface 1910a and a bottom surface 1910b. An electrical device 1920 and routing conductors 1922a and 1922b are on the top surface 1910b. The electrical device 1920 is in electrical communication with at least one transparent conductive via 1900a, which is in electrical communication with the transparent conductive via 1900b through the buried conductive routing 1985a. The routing conductor 1922b on the top surface 1910a is in electrical communication with the buried electrical device 1980 through the transparent conductive via 1900c and the buried routing conductor 1985b. The electrical devices 1920 and 1980 can include a transparent or non-transparent contact pad or other passive elements such as a resistor, a capacitor, or an inductor, or an active element such as an integrated circuit, an optoelectronic device, a sensor, or a MEMS device, for example. The routing conductors 1922a, 1922b, 1985a and 1985b can be transparent or non-transparent. In some implementations, the electrical devices 1920 and 1980 can be outside a viewable area and the transparent routing conductors 1922a, 1922b, 1985a and 1985b can be directed from within the viewable area to the periphery of the viewable area.

Partially through vias, such as the transparent conductive vias 1900a-1900c in the example of FIG. 19, can connect conductors such as electrical contacts, pads and/or conductive routing on one or more layers of the transparent substrate 1910. In some implementations, partially through vias can be formed on one or both sides of the transparent substrate 1910. In some implementations, the transparent conductive vias 1900 can extend through one or more dielectric layers within the transparent substrate 1910. In some implementations, the transparent substrate 1910 can include a glass PCB. Various methods can be used to form the multiple layers in the transparent substrate 1910, as described above in reference to FIG. 15. In some implementations, each layer of the transparent substrate 1910 can be formed by depositing or otherwise disposing the layers on one or both sides of the substrate. In some implementations, each layer of the transparent substrate 1910 can be formed layer by layer using multiple transparent substrates, which are then attached or laminated together. In some implementations, each layer of the transparent substrate 1910 can be formed by depositing one or more spin-on glass (SOG) or epoxy layers over a base substrate layer. Buried electrical devices 1980 and conductive routing 1985a and 1985b can be formed between depositions of the SOG or epoxy layers.

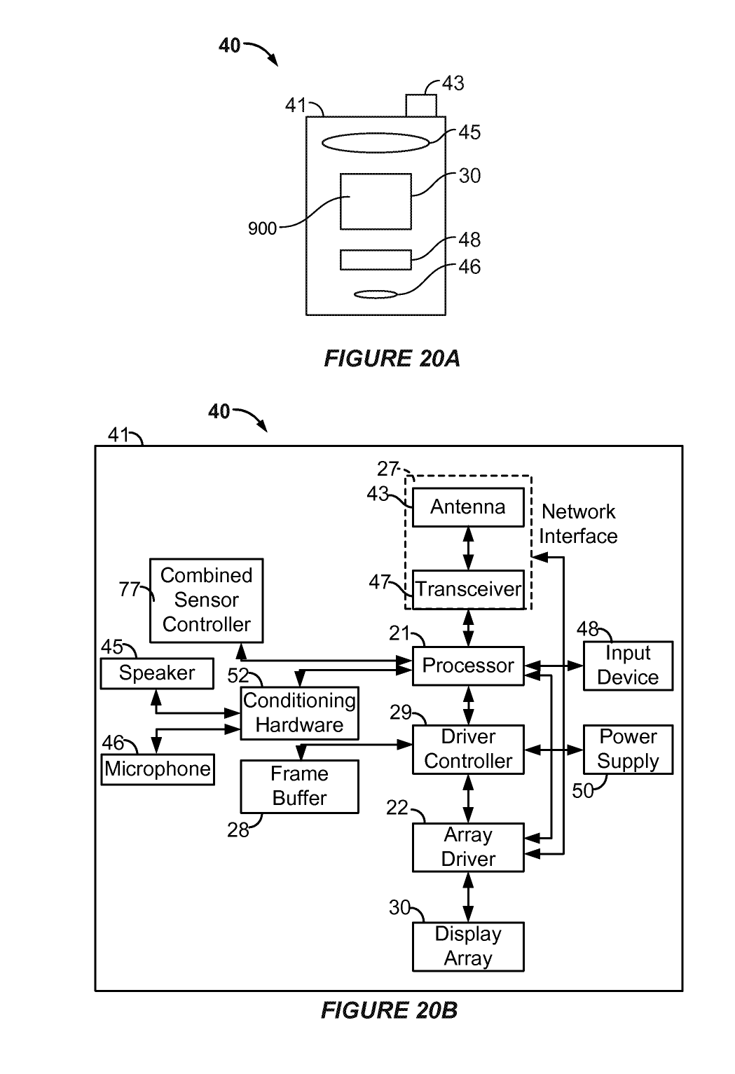

In some implementations, conductive transparent vias can be used to provide electrical connections to interferometric modulators. FIGS. 20A and 20B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 20B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a transparent substrate including a top surface and a bottom surface;
a topside conductor on the top surface and a bottom side conductor on the bottom surface; and
a transparent conductive via extending through the transparent substrate, wherein the transparent conductive via electrically connects the topside conductor to the bottom side conductor.

2. The apparatus of claim 1, wherein the transparent conductive via includes a via hole that extends through the transparent substrate and one or more transparent conductive materials that coat an interior surface of the via hole.

3. The apparatus of claim 2, wherein the transparent conductive materials include a transparent conductive oxide.

4. The apparatus of claim 2, wherein the via further includes a transparent non-conductive material that at least partially fills the via hole.

5. The apparatus of claim 2, wherein the transparent conductive material has a thickness between about 100 Å and about 2 microns.

6. The apparatus of claim 1, wherein the via includes a via hole that extends through the transparent substrate and one or more transparent conductive materials that fill the via hole.

7. The apparatus of claim 6, wherein the conductive transparent materials are selected from the group consisting of a transparent conductive polymer, a nanotube-filled resin, a metal nanowire-filled resin, a particle-filled resin, a metal particle-filled resin, a polyelectrolyte, a polymer gel electrolyte, a bicontinuous phase-separated blend of a conductive polymer and a non-conductive polymer, and a microphase-separated block copolymer including conductive and non-conductive blocks.

8. The apparatus of claim 1, wherein at least one of the topside conductor and the bottom side conductor is transparent.

9. The apparatus of claim 1, further comprising transparent conductive routing on the top or bottom surface of the transparent substrate in electrical communication with the transparent conductive via.

10. The apparatus of claim 1, wherein a thickness of the transparent substrate is between about 10 microns and about 50 microns.

11. The apparatus of claim 1, wherein a thickness of the transparent substrate is between about 50 microns and about 700 microns.

12. The apparatus of claim 1, wherein a diameter of the transparent conductive via is between about 3 microns and 10 microns.

13. The apparatus of claim 1, wherein a diameter of the transparent conductive via is between about 10 microns and about 700 microns.

14. The apparatus of claim 1, wherein the transparent conductive via has an electrical resistance between about 10 ohms and about 10,000 ohms.

15. The apparatus of claim 1, further comprising an array of transparent conductive vias extending through the transparent substrate.

16. The apparatus of claim 15, wherein the transparent conductive vias provide an electrical connection to one or more integrated circuit, optoelectronic, or MEMS devices.

17. The apparatus of claim 1, wherein the apparatus is a display or a touch sensor.

18. The apparatus of claim 1, further comprising:
a display;
a processor that is configured to communicate with the display, the processor being configured to process image data; and
a memory device that is configured to communicate with the processor.

19. The apparatus of claim 18, further comprising:
a driver circuit configured to send at least one signal to the display.

20. The apparatus of claim 19, wherein the display is in electrical communication with at least one of the processor and the driver circuit through the transparent conductive via.

21. The apparatus of claim 19, further comprising:
a controller configured to send at least a portion of the image data to the driver circuit.

22. The apparatus of claim 18, further comprising:
an image source module configured to send the image data to the processor, wherein the image source module includes at least one of a receiver, transceiver, and transmitter.

23. The apparatus of claim 18, further comprising:
an input device configured to receive input data and to communicate the input data to the processor.

24. The apparatus of claim 23, wherein the input device includes a touch sensor in electrical communication with the processor through the transparent conductive via.

25. An apparatus comprising:
a transparent substrate including a top surface and a bottom surface;
a topside conductor on the top surface; and
a transparent conductive via extending at least partially through the transparent substrate, wherein the transparent conductive via is in electrical communication with the topside conductor.

26. The apparatus of claim 25, further comprising a transparent ground plane disposed within or on the bottom surface of the transparent substrate, wherein the transparent conductive via provides a conductive pathway from the topside conductor to the transparent ground plane.

27. The apparatus of claim 25, wherein the transparent conductive via electrically connects the topside conductor to an electrical trace or device that is positioned between the top surface and the bottom surface of the transparent substrate.

28. An apparatus comprising:
a transparent substrate including a top surface and a bottom surface;
a topside means for conducting electricity on the top surface and a bottom side means for conducting electricity on the bottom surface; and
a transparent means for conducting electricity through the transparent substrate, wherein the transparent means electrically connects the topside means to the bottom side means.

29. The apparatus of claim 28, wherein at least one of the topside means and the bottom side means is a transparent conductive trace.

30. The apparatus of claim 28, wherein the transparent means for conducting electricity through the transparent substrate is a transparent conductive via.

31. A method comprising:
providing a transparent substrate having a top surface and a bottom surface;
forming a topside conductor on the top surface and a bottom side conductor on the bottom surface;
forming a via hole in the transparent substrate; and
forming a transparent conductive via extending through the transparent substrate and in electrical communication with the topside conductor and the bottom side conductor.

32. The method of claim 31, wherein forming the transparent conductive via includes filling the via hole with a transparent conductive material.

33. The method of claim 31, wherein forming the transparent conductive via includes coating the via hole with a transparent conductive material.

34. The method of claim 33, wherein forming the transparent conductive via further includes filling the via hole with an electrically non-conductive transparent material.

35. The method of claim 31, wherein forming the transparent conductive via includes depositing a transparent conductive oxide on an interior surface of the via hole.

36. The method of claim 31, wherein forming the transparent conductive via includes coating the via hole with a transparent conductive polymer.

37. A method comprising:
providing a first transparent substrate including a top surface and a bottom surface of the first transparent substrate, a topside conductor on the top surface of the first transparent substrate and a bottom side conductor on the bottom surface of the first transparent substrate, and a first transparent conductive via extending through the first transparent substrate, wherein the first transparent conductive via electrically connects the topside conductor to the bottom side conductor of the first transparent substrate; and
forming a second transparent substrate on the first transparent substrate, the second transparent substrate including a top surface and a bottom surface of the second transparent substrate, a topside conductor on the top surface of the second transparent substrate and a bottom side conductor on the bottom surface of the second transparent substrate, and a second transparent conductive via extending through the second transparent substrate, wherein the second transparent conductive via electrically connects the topside conductor to the bottom side conductor of the second transparent substrate.

38. The method of claim 37, further comprising laminating the first transparent substrate and the second transparent substrate to form a multi-layered transparent substrate.

39. The method of claim 37, wherein forming the second transparent substrate includes applying a spin-on dielectric or epoxy on the first transparent substrate.
